(19) United States
(12) Patent Application Publication
(10) Pub. No.: US 2024/0290580 A1
(43) Pub. Date: Aug. 29, 2024

(54) Gas Distribution Plate with Enhanced Gas Hole Consistency and Extended Life

(71) Applicant: Applied Materials, Inc., Santa Clara, CA (US)

(72) Inventor: Sam KIM, San Jose, CA (US)

(21) Appl. No.: 18/421,872

(22) Filed: Jan. 24, 2024

Related U.S. Application Data
(60) Provisional application No. 63/448,195, filed on Feb. 24, 2023.

(51) Int. Cl. H01J 37/32

(52) U.S. Cl. CPC H01J 37/3244; H01J 37/32082

(57) ABSTRACT

Embodiments of gas distribution plates for use with process chambers are provided herein. In some embodiments, a gas distribution plate includes: a body comprising a substantially flat plate made from a first material; a plurality of gas distribution holes extending through the body, wherein the plurality of gas distribution holes have a diameter that varies through the body, and wherein a throat of the plurality of gas distribution holes corresponds with a location where the diameter of the gas distribution holes is smallest; and a bushing at least partially disposed in each of the plurality of gas distribution holes, wherein the bushing comprises a bottom plate that includes an orifice with a diameter smaller than the diameter of the throat and sidewalls extending from the bottom plate, and wherein the bushing is made of a second material different from the first material.

### CROSS-REFERENCE TO RELATED APPLICATIONS

This application claims benefit of U.S. provisional patent application Ser. No. 63/448,195, filed Feb. 24, 2023, which is herein incorporated by reference in its entirety.

### FIELD

Embodiments of the present disclosure generally relate to substrate processing equipment.

### BACKGROUND

In semiconductor substrate processing, a gas distribution plate, such as a showerhead or a faceplate, having gas holes are typically used to distribute process gases in a process chamber. The lifetime of the gas distribution plate is limited due to gas hole size changes over time from processing substrates and during cleaning processes performed on the gas distribution plate. For example, chemical cleaning may be used to remove residues and contaminants from the gas distribution plate. Each time a chemical cleaning process is performed, the gas hole sizes (i.e., hole diameter) increase and eventually the sizes of the gas holes increase beyond a design specification. Moreover, gas holes having a small size may be difficult to drill with adequate control and with hole-to-hole consistency due to vibration of the gas distribution plate during drilling and thickness of the gas distribution plate.

Accordingly, the inventor has provided herein embodiments of improved gas distribution plates.

### SUMMARY

Embodiments of gas distribution plates for use with process chambers are provided herein. In some embodiments, a gas distribution plate includes: a body comprising a substantially flat plate made from a first material; a plurality of gas distribution holes extending through the body, wherein the plurality of gas distribution holes have a diameter that varies through the body, and wherein a throat of the plurality of gas distribution holes corresponds with a location where the diameter of the gas distribution holes is smallest; and a bushing at least partially disposed in each of the plurality of gas distribution holes, wherein the bushing comprises a bottom plate that includes an orifice with a diameter smaller than the diameter of the throat and sidewalls extending from the bottom plate, and wherein the bushing is made of a second material different from the first material.

In some embodiments, a body comprising a substantially flat plate made of metal; a plurality of gas distribution holes extending through the body, wherein the plurality of gas distribution holes have a diameter that decreases from an upper surface of the body to a throat of the plurality of gas distribution holes and increases from a throat to a lower surface of the body, and wherein the throat corresponds with a location where the diameter of the gas distribution holes is smallest; and a bushing disposed in each of the plurality of gas distribution holes, wherein the bushing comprises a bottom plate that includes an orifice with a diameter smaller than the diameter of the throat and sidewalls extending from the bottom plate, and wherein the bushing is made of a ceramic material.

In some embodiments, a process chamber, includes: a chamber body having an interior volume thereon; a substrate support disposed in the interior volume and configured to support a substrate; and a gas distribution plate disposed in the interior volume and comprising: a body comprising a substantially flat plate made of a first material; a plurality of gas distribution holes extending through the body, wherein the plurality of gas distribution holes have a diameter that varies through the body, and wherein a throat of the plurality of gas distribution holes corresponds with a location where the diameter of the gas distribution holes is smallest; and a bushing at least partially disposed in each of the plurality of gas distribution holes, wherein the bushing comprises a bottom plate that includes an orifice with a diameter smaller than the diameter of the throat and sidewalls extending from the bottom plate, and wherein the bushing is made of a second material difference from the first material.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber having a gas distribution plate in accordance with at least some embodiments of the present disclosure.

FIG. 2 depicts a close-up cross-sectional side view of a gas distribution plate having a bushing in accordance with at least some embodiments of the present disclosure.

FIG. 3 depicts a close-up cross-sectional side view of a gas distribution plate having a bushing in accordance with at least some embodiments of the present disclosure.

FIG. 4 depicts a close-up cross-sectional side view of a gas distribution plate having a bushing in accordance with at least some embodiments of the present disclosure.

FIG. 5 depicts a close-up cross-sectional side view of a gas distribution plate having a bushing that is screw fit in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of gas distribution plates having gas distribution holes at least partially defined by a bushing made of a material that does not erode when exposed to process gases or chemical cleaning fluids are provided herein. For example, the bushing may define an orifice for the plurality of gas distribution holes such that with chemical cleaning or other processing, the size of the orifice does not increase. In some embodiments, the bushing advantageously may be made of a non-corrosive material, for example, a ceramic material or other materials having good resistance against common cleaning chemicals such as alcohol, weak acids, or the like. The orifice of the bushing may also advantageously be drilled/formed outside of a body of the gas distribution plate and subsequently coupled to the gas distribution plate. Accordingly, the orifice of the bushing advantageously may be drilled/formed with better control and better hole-to-hole consistency as compared to conventional gas distribution plates.

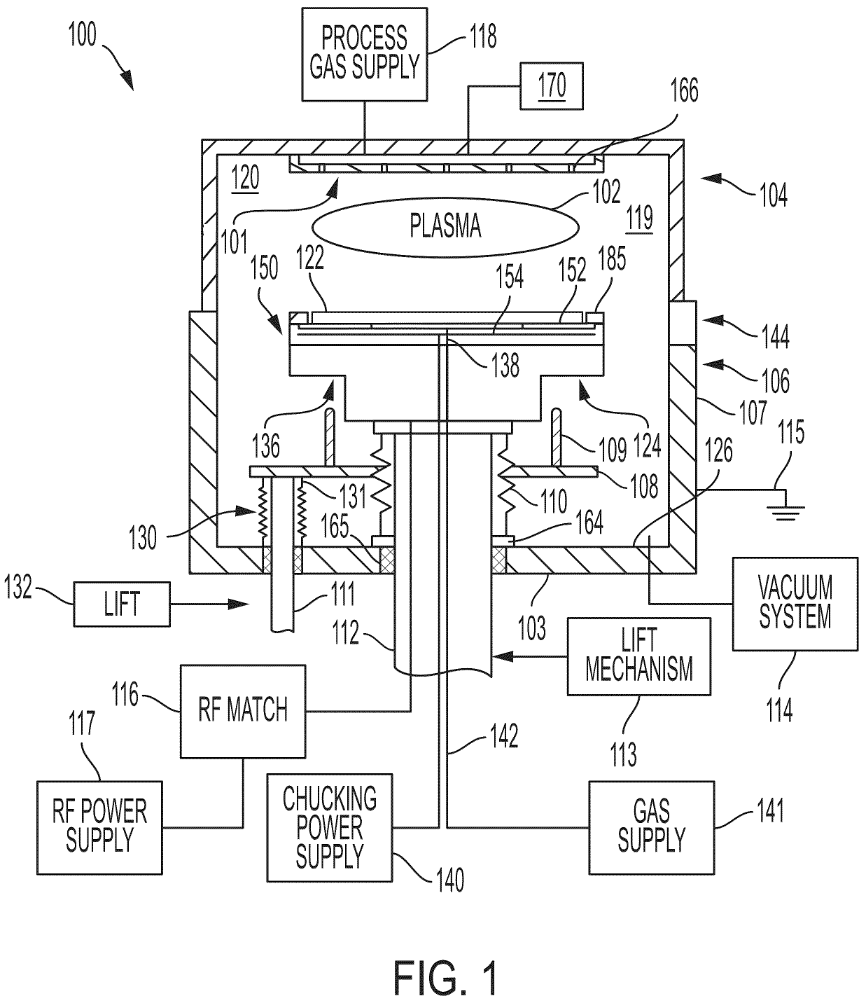

FIG. 1 depicts a schematic side view of a process chamber having a gas distribution plate in accordance with at least some embodiments of the present disclosure. In some embodiments, the process chamber 100 is an etch chamber, a deposition chamber, or any other suitable chamber for substrate processing that includes a gas distribution plate 101. In some embodiments, the process chamber 100 is a plasma chamber. In some embodiments, the process chamber 100 is a vacuum chamber that is suitably adapted to maintain sub-atmospheric pressures within an interior volume 120 during substrate processing. The process chamber 100 includes a chamber body 106 having a bottom plate 103, a lid 104, and sidewalls 107 extending from the bottom plate 103 to the lid 104. The chamber body 106 is made of a suitable material, for example, aluminum.

A substrate support 124 is disposed within the interior volume 120 to support and retain a substrate 122, such as a semiconductor wafer, for example, or other such substrate as may be retained. The substrate support 124 may generally comprise a pedestal 150 coupled to a hollow shaft 112. The pedestal 150 comprises an ESC 152 disposed on a base assembly 136. In some embodiments, the substrate support 124 may include an edge ring 185 disposed on the ESC 152. The ESC 152 may include one or more chucking electrodes 154 configured to electrostatically chuck the substrate 122 to the ESC 152. The one or more chucking electrodes 154 may also electrostatically chuck the edge ring 185 to the ESC 152. In some embodiments, the ESC 152 is made of a ceramic material, for example aluminum oxide (Al₂O₃).

The hollow shaft 112 provides a conduit to provide, for example, backside gases, process gases, fluids, coolants, power, or the like, to the pedestal 150. In some embodiments, the hollow shaft 112 is coupled to a lift mechanism 113, such as an actuator or motor, which provides vertical movement of the pedestal 150 between an upper, processing position and a lower, transfer position. A bellows assembly 110 is disposed about the hollow shaft 112 and is coupled between the pedestal 150 and a bottom surface 126 of the process chamber 100 to provide a flexible seal that allows vertical motion of the pedestal 150 while preventing loss of vacuum from within the process chamber 100. The bellows assembly 110 also includes a lower bellows flange 164 in contact with an o-ring 165 or other suitable sealing element which contacts the bottom surface 126 to help prevent loss of chamber vacuum.

In some embodiments, the gas distribution plate 101 is disposed in the interior volume 120 proximate the lid 104 and opposite the substrate support 124 for delivering process gases into the interior volume 120. The gas distribution plate 101 includes a plurality of gas distribution holes 166. The process chamber 100 is coupled to and in fluid communication with a process gas supply 118 which may supply one or more process gases to the process chamber 100 via the plurality of gas distribution holes 166 for processing the substrate 122. The interior volume 120 may include a processing volume 119 located in the upper half of the interior volume 120 and generally between the substrate support 124 and the gas distribution plate 101. The process chamber 100 may also include one or more shields (not shown) circumscribing various chamber components to prevent unwanted reaction between such components and ionized process material. The chamber body 106 may be made of metal, such as aluminum. The chamber body 106 may be grounded via a coupling to ground 115.

In some embodiments, the hollow shaft 112 facilitates coupling a backside gas supply 141, a chucking power supply 140, and RF power sources (e.g., RF plasma power supply 170 and a bias power supply 117) to the pedestal 150. In some embodiments, the bias power supply 117 includes one or more RF bias power sources. In some embodiments, RF energy supplied by the RF plasma power supply 170 may have a frequency of about 400 kHz to over 40 MHz. The backside gas supply 141 is disposed outside of the chamber body 106 and supplies heat transfer gas to the pedestal 150. In some embodiments, a RF plasma power supply 170 and a bias power supply 117 are coupled to the pedestal 150 via respective RF match networks (only RF match network 116 shown). In some embodiments, the substrate support 124 may alternatively include AC, DC, or RF bias power. In some embodiments, the AC, DC, or RF bias power may be pulsed.

The process chamber 100 may include a second lift 130. The second lift 130 can include a plurality of lift pins 109 mounted on a platform 108 connected to a shaft 111 which is coupled to a second lift mechanism 132 for raising and lowering the second lift 130. The plurality of lift pins 109 may extend through the ESC 152 so that the substrate 122 may be placed on or removed from the pedestal 150. In some embodiments, each of the lift pins 109 are not mounted to a common platform and are independently controllable. The pedestal 150 may include through holes to receive one or more of the lift pins 109. A bellows assembly 131 is coupled between the second lift 130 and bottom surface 126 to provide a flexible seal which maintains the chamber vacuum during vertical motion of the second lift 130. In some embodiments, as shown in FIG. 1, the second lift 130 is disposed outside of the hollow shaft 112.

The pedestal 150 may include gas distribution channels 138 extending, for example, from a lower surface of the pedestal 150 (e.g., bottom surface of the base assembly 136) to various openings in an upper surface of the pedestal 150. The gas distribution channels 138 are configured to provide backside gas, such as nitrogen (N) or helium (He), to the upper surface of the pedestal 150 to act as a heat transfer medium. The gas distribution channels 138 are in fluid communication with the backside gas supply 141 via gas conduit 142 to control the temperature and/or temperature profile of the pedestal 150 during use.

The process chamber 100 is coupled to and in fluid communication with a vacuum system 114 which includes a throttle valve (not shown) and vacuum pump (not shown) which are used to exhaust the process chamber 100. The pressure inside the process chamber 100 may be regulated by adjusting the throttle valve and/or vacuum pump. The process chamber 100 includes a slit valve 144 having a substrate transfer opening that is selectively opened or closed to facilitate transferring the substrate 122 into and out of the interior volume 120. In some embodiments, a transfer robot (not shown) having one or more transfer blades is configured to transfer the substrate 122.

In operation, for example, a plasma 102 may be created in the interior volume 120 to perform one or more processes. The plasma 102 may be created by coupling power from a plasma power source (e.g., RF plasma power supply 170) to a process gas via one or more electrodes near or within the interior volume 120 to ignite the process gas and creating the plasma 102. A bias power may be provided from a bias power supply (e.g., bias power supply 117) to the pedestal 150 to attract ions from the plasma 102 towards the substrate 122. The bias power supply 117 may supply bias power to the edge ring 185 and the ESC 152. For example, the bias power supply 117 may comprise a single power supply that is shared by both the edge ring 185 and the ESC 152. Backside gas, or heat transfer gas, may be provided to the substrate 122 via gas conduit 142 to control the temperature and/or temperature profile of the pedestal 150 during use.

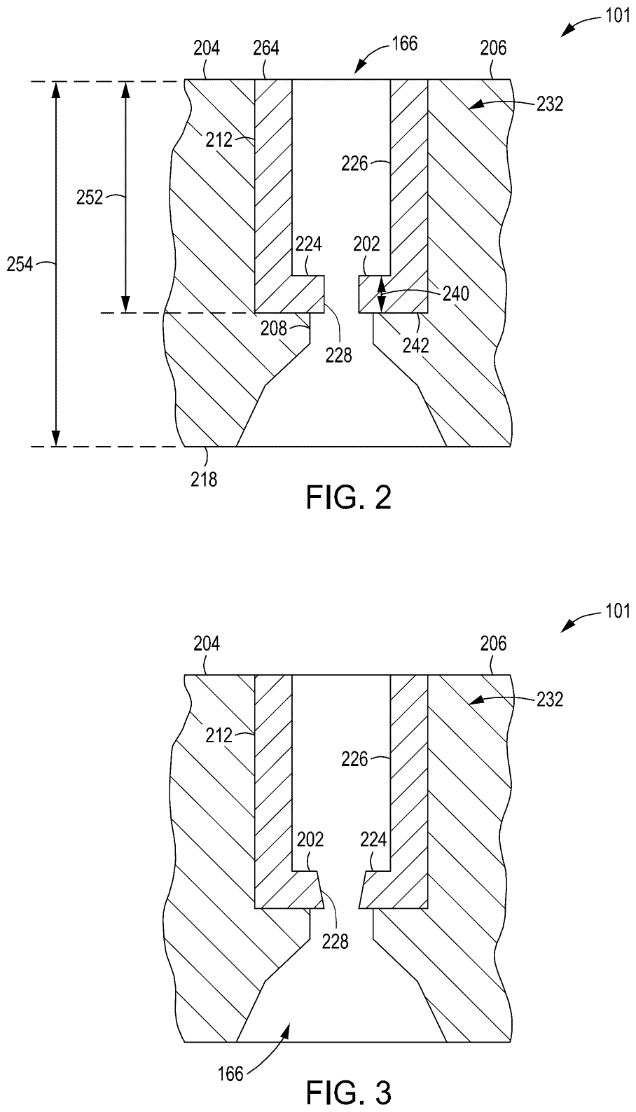

FIG. 2 depicts a close-up cross-sectional side view of a gas distribution plate having a bushing in accordance with at least some embodiments of the present disclosure. The gas distribution plate 101 generally includes a body 204 comprising a substantially flat plate made of a first material. The plurality of gas distribution holes 166 extend through the body 204.

In some embodiments, the plurality of gas distribution holes 166 have a diameter that varies through the body 204 in any suitable manner. A throat 208 of the plurality of gas distribution holes 166 corresponds with a location where the diameter of the gas distribution holes 166 is smallest. In some embodiments, the first material is metal, such as aluminum or stainless steel.

In some embodiments, the diameter of each of the plurality of gas distribution holes 166 decreases or is substantially constant from an upper surface 206 of the body 204 to the throat 208. In some embodiments, the diameter of each of the plurality of gas distribution holes 166 increases from the throat 208 to a lower surface 218 of the body 204. In some embodiments, the diameter of each of the plurality of gas distribution holes 166 is greatest proximate the lower surface 218. In some embodiments, there is no line of sight of inner surfaces of the body 204 proximate the gas distribution holes 166 from a top view of the gas distribution plate 101 when the bushings 212 are installed in the gas distribution plate 101.

In some embodiments, a bushing 212 is at least partially disposed in each of the plurality of gas distribution holes 166. The bushing 212 comprises a bottom plate 224 and sidewalls 226 extending from the bottom plate 224 towards the upper surface 206. In some embodiments, the sidewalls 226 of the bushing 212 form a cylinder. The bottom plate 224 includes an orifice 228 with a diameter smaller than the diameter of the throat 208 such that the orifice 228 defines a flow through each of the gas distribution holes 166. For example, the diameter and a length 240 of the orifice 228 are configured to control a gas flow through the gas distribution plate 101. In some embodiments, a diameter of the orifice is about 0.01 to about 0.05 inches. In some embodiments, the bushing 212 is disposed in an upper portion 232 of the body 204. In some embodiments, an upper surface 202 of the bottom plate 224 is substantially flat.

In some embodiments, as depicted in FIG. 2, the orifice 228 has a substantially constant diameter. FIG. 3 depicts a close-up cross-sectional side view of a gas distribution plate 101 having a bushing 212 in accordance with at least some embodiments of the present disclosure. In some embodiments, as depicted in FIG. 3, the orifice 228 has a diameter that varies. In some embodiments, the diameter of the orifice 228 decreases from the upper surface 202 to a lower surface 242 of the bottom plate 224.

The bushing 212 is made of a second material. The second material is different from the first material. In some embodiments, the second material is more corrosion resistant than the first material. For example, the bushing 212 is made of a non-corrosive material so that the orifice 228 does not erode during processing of the substrate 122 and cleaning of the gas distribution plate 101, advantageously increasing the life span of the gas distribution plate 101. In some embodiments, the bushing 212 is made of a ceramic material, for example, silicon carbide (SiC). In some embodiments, the bushing 212 is press fit into each of the plurality of gas distribution holes 166.

In some embodiments, a height 252 of the bushing 212 is less than half of a thickness 254 of the gas distribution plate 101. In some embodiments, the height 252 of the bushing 212 is more than half of the thickness 254 of the gas distribution plate 101. In some embodiments, an upper surface 264 of the bushing 212 is coplanar with an upper surface 206 of the body 204. In some embodiments, the bushing 212 is disposed entirely in the gas distribution plate 101.

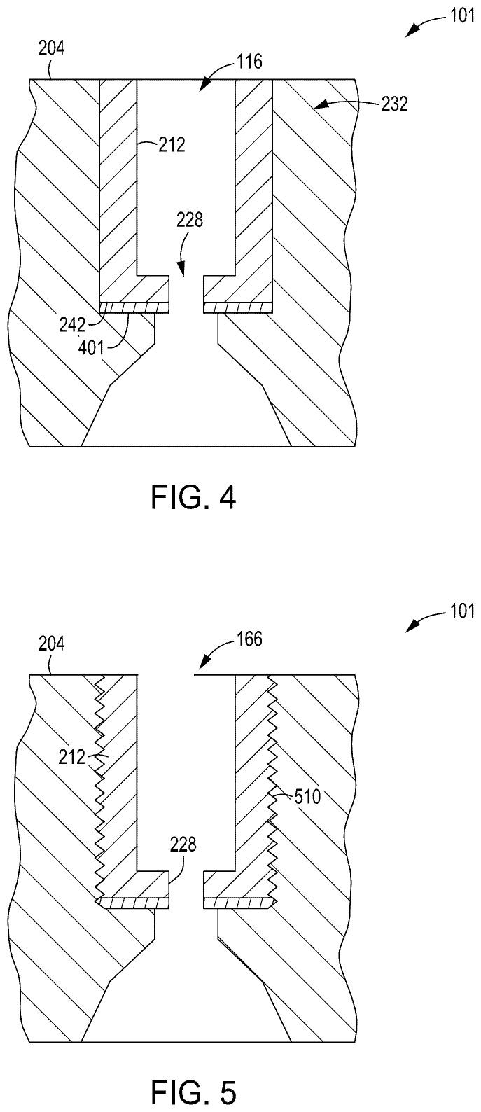

FIG. 4 depicts a close-up cross-sectional side view of a gas distribution plate having a bushing in accordance with at least some embodiments of the present disclosure. In some embodiments, the lower surface 242 of the bushing 212 includes a metal coating 401. In some embodiments, the metal coating 401 is an aluminum or stainless steel coating. The metal coating 401 advantageously contains the plasma 102 and prevents the plasma 102 from extending to the upper portion 232 of the body 20. In some embodiments, the metal coating 401 is a metal plating.

FIG. 5 depicts a close-up cross-sectional side view of a gas distribution plate having a bushing 212 that is screw fit in accordance with at least some embodiments of the present disclosure. In some embodiments, the bushing 212 includes a threaded outer surface 510 and is coupled to the body 204 via the threaded outer surface 510.

In some embodiments, the term substantially used herein may comprise within 20%. In some embodiments, the term substantially used herein may comprise within 10%. While the foregoing is directed to embodiments of the present disclosure, other and further embodiments of the disclosure may be devised without departing from the basic scope thereof.

1. A gas distribution plate for a process chamber, comprising:
a body comprising a substantially flat plate made from a first material;
a plurality of gas distribution holes extending through the body, wherein the plurality of gas distribution holes have a diameter that varies through the body, and wherein a throat of the plurality of gas distribution holes corresponds with a location where the diameter of the gas distribution holes is smallest; and
a bushing at least partially disposed in each of the plurality of gas distribution holes, wherein the bushing comprises a bottom plate that includes an orifice with a diameter smaller than the diameter of the throat and sidewalls extending from the bottom plate, and wherein the bushing is made of a second material different from the first material.

2. The gas distribution plate of claim 1, wherein a lower surface of the bushing includes a metal coating.

3. The gas distribution plate of claim 1, wherein the second material is more corrosion resistant than the first material.

4. The gas distribution plate of claim 1, wherein the bushing is press fit into the plurality of gas distribution holes.

5. The gas distribution plate of claim 1, wherein the bushing includes a threaded outer surface and is coupled to the body via the threaded outer surface.

6. The gas distribution plate of claim 1, wherein the first material is metal and the second material is ceramic.

7. The gas distribution plate of claim 1, wherein the orifice has a substantially constant diameter.

8. The gas distribution plate of claim 1, wherein the bushing is disposed in an upper portion of the body.

9. The gas distribution plate of claim 1, wherein the diameter of each of the plurality of gas distribution holes decreases from an upper surface of the body to the throat and increases from the throat to a lower surface of the body.

10. A gas distribution plate for a process chamber, comprising:
a body comprising a substantially flat plate made of metal;
a plurality of gas distribution holes extending through the body, wherein the plurality of gas distribution holes have a diameter that decreases from an upper surface of the body to a throat of the plurality of gas distribution holes and increases from a throat to a lower surface of the body, and wherein the throat corresponds with a location where the diameter of the gas distribution holes is smallest; and
a bushing disposed in each of the plurality of gas distribution holes, wherein the bushing comprises a bottom plate that includes an orifice with a diameter smaller than the diameter of the throat and sidewalls extending from the bottom plate, and wherein the bushing is made of a ceramic material.

11. The gas distribution plate of claim 10, wherein a lower surface of the bushing includes an aluminum coating.

12. The gas distribution plate of claim 10, wherein the orifice has a diameter that varies.

13. The gas distribution plate of claim 10, wherein the sidewalls of the bushing form a cylinder.

14. The gas distribution plate of claim 10, wherein a diameter of the orifice is about 0.01 to about 0.05 inches.

15. The gas distribution plate of claim 10, wherein a height of the bushing is less than half of a thickness of the gas distribution plate.

16. A process chamber, comprising:
a chamber body having an interior volume thereon;
a substrate support disposed in the interior volume and configured to support a substrate; and
a gas distribution plate disposed in the interior volume and comprising:
a body comprising a substantially flat plate made of a first material;
a plurality of gas distribution holes extending through the body, wherein the plurality of gas distribution holes have a diameter that varies through the body, and wherein a throat of the plurality of gas distribution holes corresponds with a location where the diameter of the gas distribution holes is smallest; and
a bushing at least partially disposed in each of the plurality of gas distribution holes, wherein the bushing comprises a bottom plate that includes an orifice with a diameter smaller than the diameter of the throat and sidewalls extending from the bottom plate, and wherein the bushing is made of a second material difference from the first material.

17. The process chamber of claim 16, wherein at least one of:
the bushing is press fit into the plurality of gas distribution holes; or
the bushing includes a threaded outer surface and is coupled to the body via the threaded outer surface.

18. The process chamber of claim 16, wherein an upper surface of the bushing is coplanar with an upper surface of the body.

19. The process chamber of claim 16, wherein the bushing is made of a ceramic material.

20. The process chamber of claim 16, wherein the process chamber is a plasma chamber.
